(19) United States
(12) Patent Application Publication
(10) Pub. No.: US 2026/0089910 A1
(43) Pub. Date: Mar. 26, 2026

(54) METHOD FOR FABRICATING A CAPACITOR

(71) Applicant: NANYA TECHNOLOGY CORPORATION, New Taipei City (TW)

(72) Inventor: Ning-Shuang HSU, New Taipei City (TW)

(21) Appl. No.: 18/892,575

(22) Filed: Sep. 23, 2024

(51) Int. Cl. H10B 12/00

(52) U.S. Cl. CPC H10B 12/03

(57) ABSTRACT

A method for fabricating a capacitor is provided. The method includes following steps. A mold is formed on an interconnect layer. A recess is formed in the mold. A bottom electrode layer is deposited on the mold and into the recess. A metal oxide layer is disposed on the bottom electrode layer and into the recess. A surface oxide layer is formed on the metal oxide layer. A non-O₂ wet etching process is performed to remove the surface oxide layer, the metal oxide layer, and the mold from the bottom electrode layer.

### BACKGROUND

### FIELD OF INVENTION

The present invention relates to a method for fabricating a capacitor.

### DESCRIPTION OF RELATED ART

A dynamic random access memory (DRAM) is a semiconductor arrangement for storing bits of data with cell capacitors within an integrated circuit. DRAMs commonly include trench capacitor DRAM cells and/or stacked capacitor DRAM cells.

### SUMMARY

According to some embodiments of the present disclosure, a method for fabricating a capacitor is provided. The present method may allow capacitors to be fabricated without increasing a thickness of a bottom electrode of the capacitor by depositing an oxidation layer on the bottom electrode and replacing the O₂ wet etching process to a non-O₂ wet etching process. Therefore the present method may reduce issues that the oxidized bottom electrode of the capacitor is consumed unevenly by an O₂ wet etching process, thus leading to the capacitor wobbling. Furthermore, the present method may reduce the thickness of the bottom electrode of the capacitor to meet the desire capacitance value. This method may provide efficient solutions to achieving good electrical performance and structure stability of the capacitor.

According to some embodiments of the present disclosure, a method for fabricating a capacitor is provided. The method includes following steps. A mold is formed on an interconnect layer. A recess is formed in the mold. A bottom electrode layer is deposited on the mold and into the recess. A metal oxide layer is disposed on the bottom electrode layer and into the recess. A surface oxide layer is formed on the metal oxide layer. A non-O₂ wet etching process is performed to remove the surface oxide layer, the metal oxide layer, and the mold from the bottom electrode layer.

According to some embodiments of the present disclosure, the method described above further includes the following steps. A top surface of the mold is lowered prior to depositing the bottom electrode layer.

According to some embodiments of the present disclosure, the method described above further includes the following steps. After the non-O₂ wet etching process, a dielectric layer is formed on the bottom electrode layer.

According to some embodiments of the present disclosure, the method described above further includes the following steps. A top electrode layer is deposited on the dielectric layer.

According to some embodiments of the present disclosure, the method is described above, in which the interconnection layer includes a metal feature, and forming the recess is performed such that the recess is directly over the metal feature.

According to some embodiments of the present disclosure, the method is described above, in which depositing the bottom electrode layer is performed such that the bottom electrode layer is in contact with a top surface of the mold.

According to some embodiments of the present disclosure, the method is described above, in which the bottom electrode layer comprises a metal nitride layer.

According to some embodiments of the present disclosure, the method is described above, in which a thickness of the metal oxide layer is 5 Å to 10 Å.

According to some embodiments of the present disclosure, the method is described above, in which the metal oxide layer includes TiOₓ.

According to some embodiments of the present disclosure, the method is described above, in which depositing the bottom electrode layer is performed such that a side surface of the bottom electrode layer is in contact with the mold.

According to some embodiments of the present disclosure, the method is described above, in which forming the surface oxide layer is performed such that the surface oxide layer is spaced apart from the bottom electrode layer by the metal oxide layer.

According to some embodiments of the present disclosure, a method for fabricating a capacitor is provided. The method includes following steps. A mold is formed on an interconnect layer. A bottom electrode layer is deposited on the mold. A metal oxide layer is disposed on a top surface of the bottom electrode layer, in which the metal oxide layer is in direct contact with the bottom electrode layer. A top surface of the metal oxide layer is oxidized. The metal oxide layer and the mold away from the bottom electrode layer are etched.

According to some embodiments of the present disclosure, the method is described above, in which the bottom electrode layer includes a metal silicide nitride layer.

According to some embodiments of the present disclosure, the method is described above, in which etching the metal oxide layer is performed with a non-O₂ etchant.

According to some embodiments of the present disclosure, the method is described above, in which a thickness of the bottom electrode layer is 5 Å to 10 Å.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method for fabricating a capacitor in accordance with some embodiments.

FIGS. 2 through 7 are cross-sectional views of the capacitor at various stages of fabrication in accordance with some embodiments of the present disclosure.

FIG. 8 is a cross-sectional view taken along a line A-A’ of FIG. 7 in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

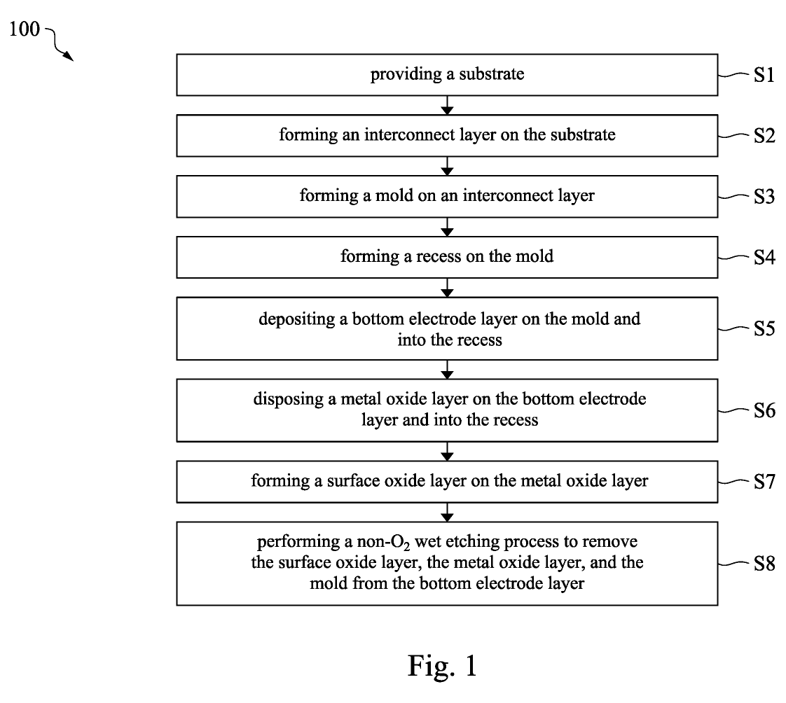

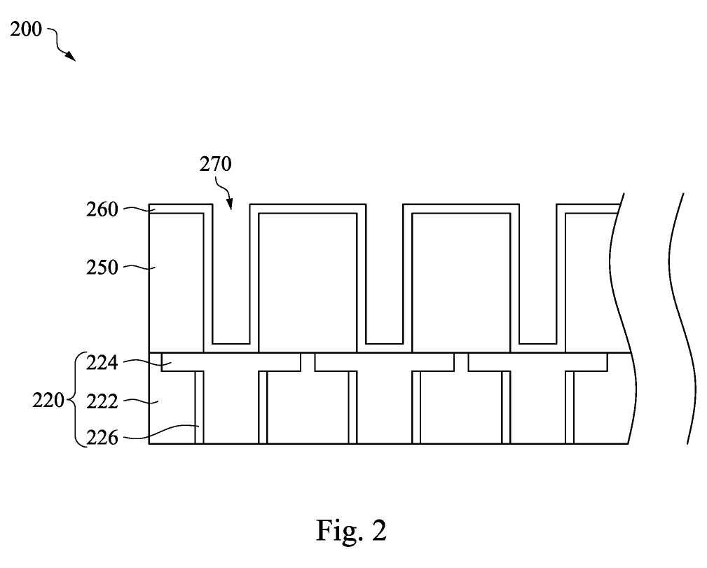

FIG. 1 is a flow chart of a method 100 for fabricating a capacitor 200 in accordance with some embodiments. FIGS. 2 through 7 are cross-sectional views of the capacitor 200 at various stages of fabrication in accordance with some embodiments of the present disclosure. The illustration is merely exemplary and is not intended to limit beyond what is specifically recited in the claims that follow. It is understood that additional operations may be provided before, during, and after the operations S1-S6 shown by FIG. 1, and some of the operations S1-S6 described below can be replaced or eliminated for additional embodiments of the method. The order of the operations/processes may be interchangeable.

Referring to FIG. 1 and FIG. 2, the method 100 begins at operations S1 and S2 where a semiconductor substrate is provided, and an interconnect layer 220 is formed over a semiconductor substrate. The interconnect layer 220 may include a dielectric material 222 and metal features 224 surrounded by the dielectric material 222. The interconnect layer 220 may be formed by etching recesses/openings in the dielectric material 222, depositing a conductive material of the metal features 224 into the recesses/openings in the dielectric material 222, followed by a planarization process to remove an excess portion of the conductive material. In some embodiments, the dielectric material 222 may include silicon oxides. In some embodiments, the conductive material of the metal features 224 may include metal deposited by chemical vapor deposition (CVD), atomic layer deposition (ALD), physical vapor deposition (PVD), the like, and/or the combination thereof. Dielectric liners 226 may be disposed between the metal features 224 and the dielectric material 222. The dielectric liners 226 may be a nitride, e.g., silicon nitride (SiN).

The method 100 proceeds to operation S3 where a mold 250 is formed on the interconnect layer 220. The mold 250 may be a material that is easily removed by the wet etching process. For example, in the other embodiment, the mold 250 may be an oxide, such as silicon oxide (SiO2), boron phosphorus silicate glass (BPSG), undoped silicon glass (USG), phosphosilicate glass (PSG), the like, and/or the combination thereof. However, it should be noticed that the mold 250 may adopt any appropriate materials without such limitation.

The method 100 proceeds to operation S4 where a recess 270 is formed in the mold 250. For example, in some embodiments, a photolithography process is performed to form a photoresist layer over the mold 250. The photolithography process may include photoresist coating, exposure, developing, baking, the like, or the combination thereof. After the photolithography process, the mold 250 is etched through the photoresist layer, and the recess 270 is formed in the mold 250, and directly over the metal feature 224.

The method 100 proceeds to operation S5 where a bottom electrode layer 260 is conformally deposited on the mold 250 and into the recess 270. The bottom electrode layer 260 may include suitable conductive materials. In some embodiments, the bottom electrode layer 260 may include a metal nitride layer or a metal silicide nitride layer, such as titanium nitride (TiN), titanium silicon nitride (TiSiN), the like, and/or the combination thereof. The material of the bottom electrode layer 260 may be chosen for better resistance to etching and high oxidation resistance. The bottom electrode layer 260 may be deposited by the chemical vapor deposition (CVD), atomic layer deposition (ALD), physical vapor deposition (PVD), the like, and/or the combination thereof. In the present embodiment, the bottom electrode layer 260 is in contact with a top surface of the mold 250, and a side surface of the bottom electrode layer 260 is in contact with the mold 250. A thickness of the bottom electrode layer 260 may be adjusted according to the functional requirements. For example, in some embodiments, the thickness of the bottom electrode layer 260 may be controlled by the number of ALD cycles.

In some embodiments, the method 100 further includes performing a planarization process to the top surface of the mold 250 prior to depositing the bottom electrode layer. The planarization process may lower the top surface of the mold 250. For example, the planarization process may be a chemical-mechanical polishing (CMP). In some other embodiments, the planarization process may be omitted.

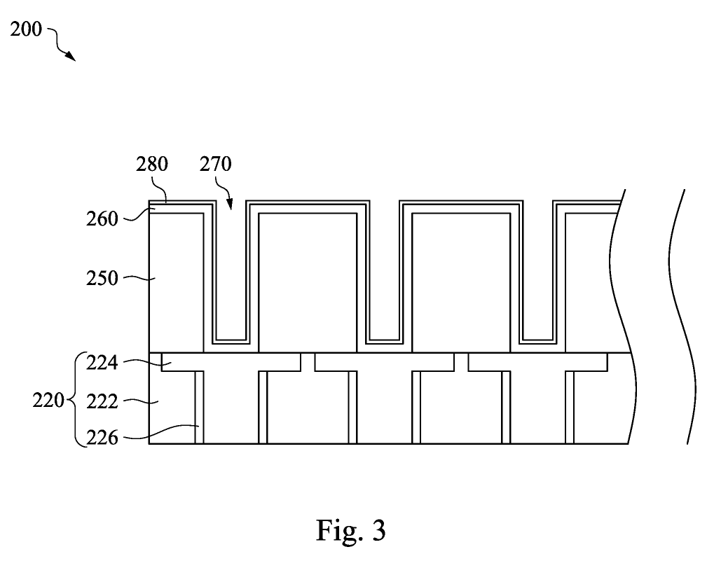

Referring to FIG. 1 and FIG. 3, the method 100 proceeds to operation S6 where a metal oxide layer 280 is disposed on the bottom electrode layer 260 and into the recess 270 after depositing the bottom electrode layer 260. The metal oxide layer 280 may include titanium oxide (TiOₓ). The metal oxide layer 280 may be disposed by CVD, ALD, PVD, the like, and/or the combination thereof. In the present embodiment, the metal oxide layer 280 is conformally disposed on a top surface of the bottom electrode layer 260, in which the metal oxide layer 280 is in direct contact with the bottom electrode layer 260. Furthermore, a thickness of the metal oxide layer 280 may be adjusted according to the functional requirements. For example, in some embodiments, the thickness of the metal oxide layer 280 may be controlled by the number of ALD cycles, and the thickness of the metal oxide layer 280 may be about 5 Å to 10 Å. However, it should be noticed that the metal oxide layer 280 may adopt any appropriate processes without such limitation.

The configuration of the metal oxide layer 280 may prevent the bottom electrode layer 260 from oxidizing.

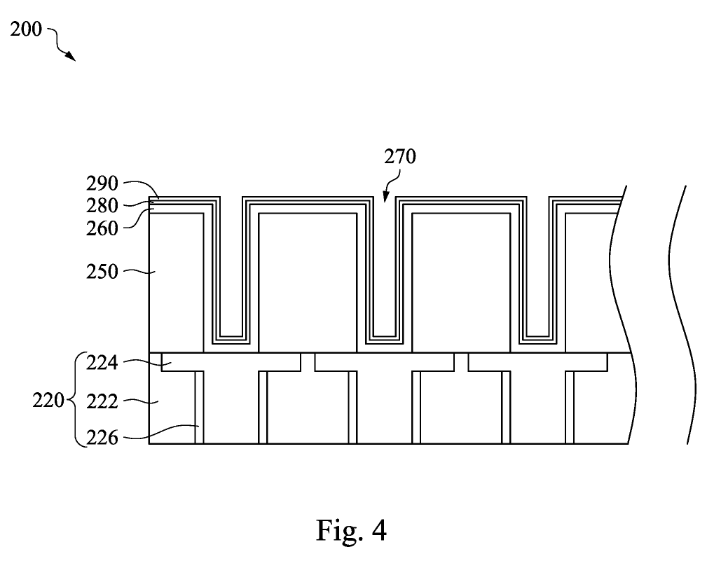

Referring to FIG. 1 and FIG. 4, the method 100 proceeds to operation S7 where a surface oxide layer 290 is formed on the metal oxide layer 280. In detail, a top surface of the metal oxide layer 280 is oxidized to form the surface oxide layer 290 during the process. With the presence of the metal oxide layer 280, the surface oxide layer 290 may be spaced apart from the bottom electrode layer 260 by the metal oxide layer 280. Therefore, the surface oxide layer 290 may prevent the bottom electrode layer 260 from oxidizing. In the present embodiment, the surface oxide layer 290 is conformally formed on a top surface of the metal oxide layer 280, in which the surface oxide layer 290 is in direct contact with the metal oxide layer 280.

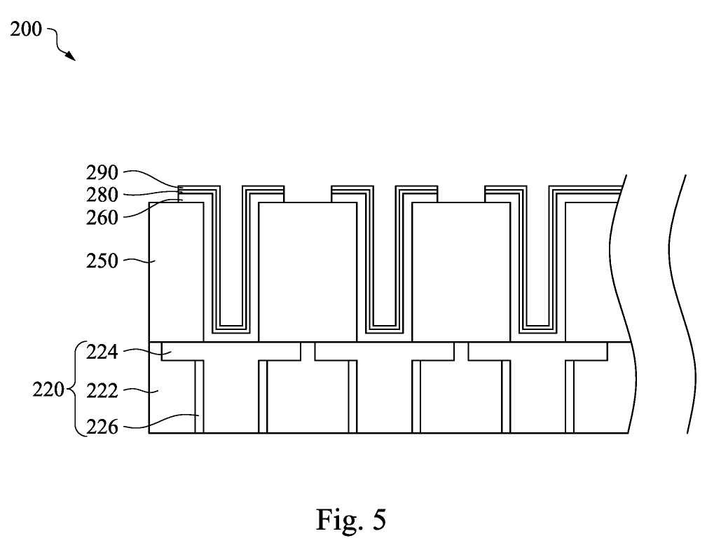

Referring to FIG. 1 and FIG. 5, in some embodiments, the method 100 may further include patterning the bottom electrode layer 260, the metal oxide layer 280 and the surface oxide layer 290 into plural separated stacks after the operation S7. For example, a photolithography process is performed to form a photoresist layer on the surface oxide layer 290. The photolithography process may include photoresist coating, exposure, developing, baking, the like, or the combination thereof. The photoresist layer may cover first portions of the surface oxide layer 290, metal oxide layer 280 and the bottom electrode layer 260, and expose second portions of the surface oxide layer 290, metal oxide layer 280 and the bottom electrode layer 260. After the formation of the photoresist layer, an etching process is performed to remove the second portions of the surface oxide layer 290, metal oxide layer 280 and the bottom electrode layer 260. The first portions of the surface oxide layer 290, metal oxide layer 280 and the bottom electrode layer 260 remains.

In addition, in the other embodiment, the method 100 may further include a planarization process or an etch back process to remove a top portion of the bottom electrode layer 260, a top portion of the metal oxide layer 280 and a top portion of the surface oxide layer 290 over a top surface of the mold 250. For example, the planarization process may include a CMP process. The etch back process or the CMP process is performed to the top portion of the bottom electrode layer 260, the top portion of the metal oxide layer 280 and the top portion of the surface oxide layer 290 until the top surface of the mold 250 is exposed.

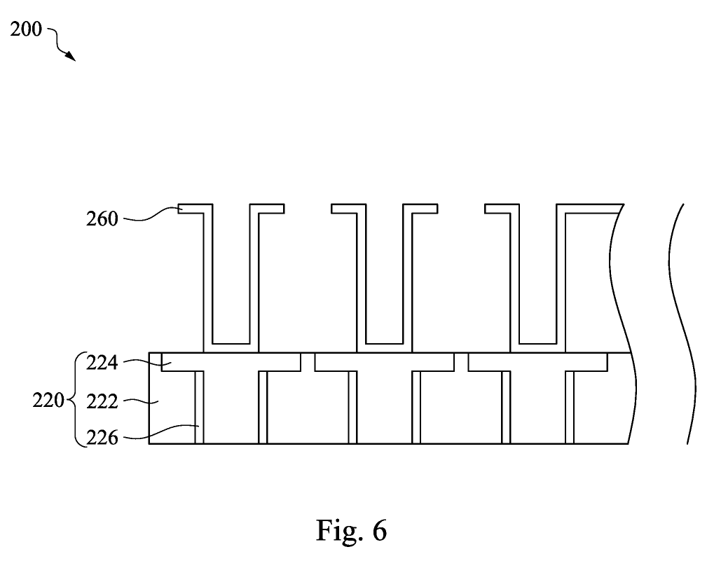

Referring to FIG. 1 and FIG. 6, the method 100 proceeds to operation S8 where a non-O₂ wet etching process is performed to remove the surface oxide layer 290, the metal oxide layer 280 and the mold 250 away from the bottom electrode layer 260, and the metal feature 224 of the interconnection layer 220 is exposed. In detail, the non-O₂ wet etching process may comprise a non-O₂ etchant, such as hydrofluoric acid, hydrofluoric acid-based, the like, and/or the combination thereof. The non-O₂ wet etching process may prevent the bottom electrode layer 260 from oxidizing during the etching process, so that may reduce issues that the oxidized bottom electrode layer 260 of the capacitor 200 is consumed unevenly by an O₂ wet etching process. However, it should be noticed that the non-O₂ wet etching process may adopt any appropriate non-O₂ etchants to remove the surface oxide layer 290, the metal oxide layer 280 and the mold 250.

Furthermore, after the non-O₂ wet etching process, the bottom electrode layer 260 may maintain good thickness uniformity due to the protection of the surface oxide layer 290 and the metal oxide layer 280. Therefore, the method 100 may improve an issue of the container wobbling of the capacitor 200 and achieve good electrical performance and structure stability of the capacitor 200, while maintaining the size of the thickness of the bottom electrode layer 260. In other word, the size of the bottom electrode layer 260 may be reduced while maintaining good thickness uniformity by performing the method 100, so that the size of the capacitor 200 may be reduced while maintaining capacitance value.

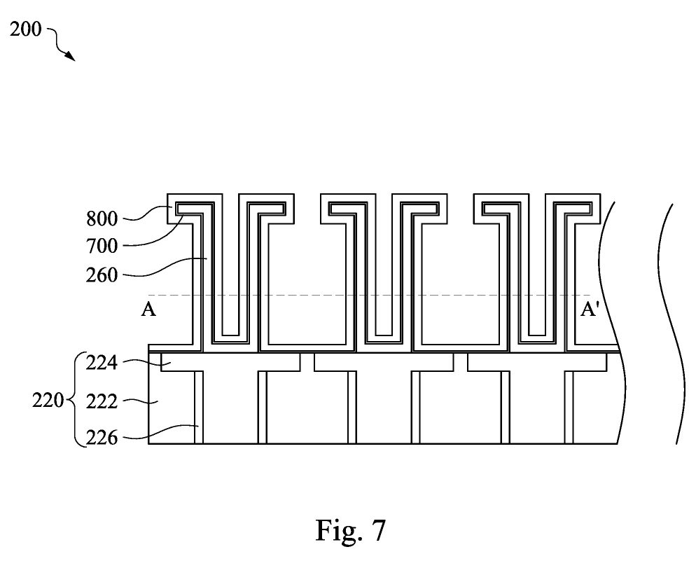

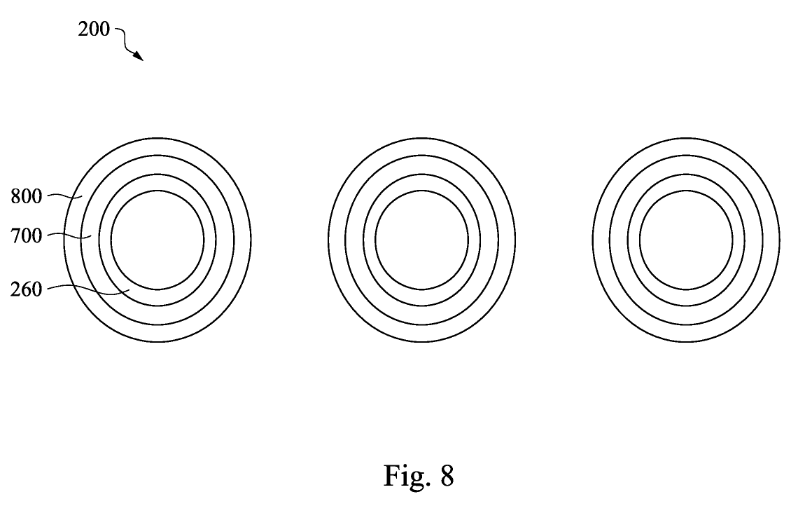

FIG. 8 is a cross-sectional view taken along a line A-A’ of FIG. 7 in accordance with some embodiments of the present disclosure. Reference is made to both FIGS. 7 and 8. The method 100 further includes forming a dielectric layer 700 on the bottom electrode layer 260 after the non-O₂ wet etching process. For example, the dielectric layer 700 may be conformally deposited over the bottom electrode layer 260 and surrounds the bottom electrode layer 260. In the other embodiment, the dielectric layer 700 further overlaps the metal feature 224 of the interconnection layer 220. In some embodiments, the dielectric layer 700 may include a high-k material. In the other embodiment, the dielectric layer 700 may include a low-k material.

The method 100 further includes depositing a top electrode layer 800 on the dielectric layer 700. For example, the top electrode layer 800 is conformally deposited the dielectric layer 700 and surrounds the bottom electrode layer 260. In the other embodiment, the top electrode layer 800 further overlaps the metal feature 224 of the interconnection layer 220. In some embodiments, the top electrode layer 800 may include the same material as the bottom electrode layer 260. In that case, as shown in FIG. 8, the bottom electrode layer 260 is surrounded by the dielectric layer 700, and the dielectric layer 700 is surrounded by the top electrode layer 800, thus forming a capacitor 200.

According to some embodiments of the present disclosure, a method for fabricating a capacitor is provided. The present method may allow capacitors to be fabricated without increasing a thickness of a bottom electrode of the capacitor by depositing an oxidation layer on the bottom electrode and replacing the O₂ wet etching process to a non-O₂ wet etching process. Therefore, the present method may reduce issues that the oxidized bottom electrode of the capacitor is consumed unevenly by an O₂ wet etching process, thus leading to the capacitor wobbling. Furthermore, the present method may reduce the thickness of the bottom electrode of the capacitor to meet the desire capacitance value. This method may provide efficient solutions to achieving good electrical performance and structure stability of the capacitor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating a capacitor, comprising:
forming a mold on an interconnect layer;
forming a recess in the mold;
depositing a bottom electrode layer on the mold and into the recess;
disposing a metal oxide layer on the bottom electrode layer and into the recess;
forming a surface oxide layer on the metal oxide layer; and
performing a non-O₂ wet etching process to remove the surface oxide layer, the metal oxide layer, and the mold from the bottom electrode layer.

2. The method of claim 1, further comprising:
lowering a top surface of the mold prior to depositing the bottom electrode layer.

3. The method of claim 1, further comprising:
after the non-O₂ wet etching process, forming a dielectric layer on the bottom electrode layer.

4. The method of claim 3, further comprising:
depositing a top electrode layer on the dielectric layer.

5. The method of claim 1, wherein the interconnection layer comprises a metal feature, and forming the recess is performed such that the recess is directly over the metal feature.

6. The method of claim 1, wherein depositing the bottom electrode layer is performed such that the bottom electrode layer is in contact with a top surface of the mold.

7. The method of claim 1, wherein the bottom electrode layer comprises a metal nitride layer.

8. The method of claim 1, wherein a thickness of the metal oxide layer is 5 Å to 10 Å.

9. The method of claim 1, wherein the metal oxide layer comprises TiOₓ.

10. The method of claim 1, wherein depositing the bottom electrode layer is performed such that a side surface of the bottom electrode layer is in contact with the mold.

11. The method of claim 10, wherein forming the surface oxide layer is performed such that the surface oxide layer is spaced apart from the bottom electrode layer by the metal oxide layer.

12. A method for fabricating a capacitor, comprising:
forming a mold on an interconnect layer;
depositing a bottom electrode layer on the mold;
disposing a metal oxide layer on a top surface of the bottom electrode layer, wherein the metal oxide layer is in direct contact with the bottom electrode layer;
oxidizing a top surface of the metal oxide layer; and
etching the metal oxide layer and the mold away from the bottom electrode layer.

13. The method of claim 12, wherein the bottom electrode layer comprises a metal silicide nitride layer.

14. The method of claim 12, wherein etching the metal oxide layer is performed with a non-O₂ etchant.

15. The method of claim 12, wherein a thickness of the bottom electrode layer is 5 Å to 10 Å.
